(19) United States
(12) Patent Application Publication
(10) Pub. No.: US 2003/0211233 A1
(43) Pub. Date: Nov. 13, 2003

(54) Manufacturing method of organic electroluminescent element

(75) Inventors: Hirofumi Kubota, Saitama (JP); Tatsuya Yoshizawa, Saitama (JP); Takako Miyake, Saitama (JP)

Correspondence Address: SUGHRUE MION, PLLC, 2100 PENNSYLVANIA AVENUE, N.W., WASHINGTON, DC, 20037, US

(73) Assignee: PIONEER CORPORATION

(21) Appl. No.: 10/379,679

(22) Filed: Mar. 6, 2003

(30) Foreign Application Priority Data
Mar. 8, 2002 (JP) P2002-063570

(51) Int. Cl. B05D 5/12; H05H 1/24

(52) U.S. Cl. 427/66; 427/68; 427/569

(57) ABSTRACT

An electrode-equipped substrate includes a substrate portion of synthetic resin and a transparent electrode. The electrode-equipped substrate is subjected to heat treatment at a temperature of 200° C. or less as well as plasma treatment before organic layers are deposited. The plasma treatment is carried out within atmosphere of (A) a mixed gas of oxygen and any one of nitrogen, argon, helium, neon and xenon, with an oxygen density of 5% or less; (B) a mixed gas of oxygen and any one of carbon tetrafluoride, hexafluoroethane, octafluoropropane and octafluorocyclobutane; or (C) a sole gas of nitrogen, argon, helium, neon, xenon, carbon monoxide, carbon dioxide, nitrogen monoxide or nitrous oxide.

The present disclosure relates to the subject matter contained in Japanese Patent Application No. 2002-63570 filed Mar. 8, 2002, which is incorporated herein by reference in its entirety.

### BACKGROUND OF THE INVENTION

1. Field of the Invention

This invention relates to a manufacturing method of an organic electroluminescent (EL) element.

2. Description of the Related Art

Conventionally, the organic electroluminescent element (organic EL element) has a structure in which organic layers such as a light emitting layer and a cathode are stacked on a substrate having a transparent electrode. These layers are formed on the substrate having a transparent electrode by vacuum evaporation or sputtering.

In manufacturing such the organic EL element, in order to prevent the light-emission luminance of the organic EL element from deteriorating, the substrate having a transparent electrode is subjected to a pretreatment before the organic layers are deposited. The pretreatment for the substrate having a transparent electrode can be carried out by a heat treatment of heating the substrate having a transparent electrode at a high temperature, a plasma treatment of using a plasma gas of only oxygen or a UV ozone treatment.

In case where the substrate having a transparent electrode is cleaned by the plasma treatment of using the plasma gas of only oxygen or the UV ozone treatment, if there is an insulating film such as resist and/or a structure such as a cathode partition, they are etched. This causes a problem of deteriorating the characteristics of the organic EL element such as light emission luminance and insulation.

On the other hand, the heat treatment at a high temperature does not deteriorate the characteristics of the organic EL element and can be efficiently employed. However, since a substrate portion of the substrate having a transparent electrode is preferably made of synthetic resin with good moldablity and the synthetic resin generally has a limit of heat resistance of about 200° C., it is difficult to heat-treat such the substrate having a transparent electrode at a temperature of 200° C. or higher. The heat treatment at a low temperature of about 200° C. leads to remarkable deterioration of the luminance when the organic EL element is preserved at a temperature of 100° C.

### SUMMARY OF THE INVENTION

An object of this invention is to provide a manufacturing method of an organic electroluminescent element (EL) in which a substrate having an electrode can be pre-treated before organic layers are deposited in order to prevent the characteristics of the organic electroluminescent element from deteriorating.

To this end, this invention intends to attain the above object by adopting the following configurations.

Specifically, a configuration is a manufacturing method of an organic electroluminescent element, comprising: preparing a electrode-equipped substrate having a substrate portion made of glass or synthetic resin; depositing organic layers including a light emitting layer on the electrode-equipped substrate; and performing both plasma treatment and heat treatment on the electrode-equipped substrate before depositing the organic layers on the electrode-equipped substrate.

The electrode formed on the substrate may be a transparent electrode that is made of ITO (indium-tin alloy), IZO (indium-zinc alloy), etc.

The synthetic resin may be polycarbonate, polymethyl methacrylate, polyallylate, polyethersulfone, polysulfone, polyethyleneterephthalate, etc.

Since both the plasma treatment and the heat treatment are carried out, the substrate having an electrode can be sufficiently pre-treated at a heating temperature of about 200° C. or lower, and an organic EL element can be manufactured without deteriorating the characteristics. Further, since the heating temperature of about 200° C. or lower can be adopted, the substrate portion may be made of synthetic resin that has lower heat resistance than glass. Since the synthetic resin is light and flexible, a light and flexible organic EL element can be manufactured.

The plasma treatment is preferably carried out within an atmosphere of (A) a mixed gas of oxygen and any one of nitrogen, argon, helium, neon and xenon, with an oxygen density of 5% or less; (B) a mixed gas of oxygen and any one of carbon tetrafluoride, hexafluoroethane, octafluoropropane and octafluorocyclobutane; or (C) a sole gas of nitrogen, argon, helium, neon, xenon, carbon monoxide, carbon dioxide, nitrogen monoxide or nitrous oxide.

Unlike the conventional technique in which a plasma treatment with only oxygen or a UV ozone treatment is performed, the plasma treatment is carried out within any atmosphere of the sole gas or mixed gas belonging to the above (A) to (C). Therefore, the etching of the insulating film such as a resist or cathode partition is difficult to occur. Particularly, although the mixed gas (A) contains oxygen, the oxygen density is 5% or less so that the etching of the insulating film such as the resist or cathode partition can be prevented.

The heat treatment is preferably carried out using a heater that is arranged in the vicinity of the substrate having an electrode.

The heat treatment using the heater enables the heating temperature to be easily adjusted.

Another configuration of this invention is a manufacturing method of an organic electroluminescent element, comprising: preparing a electrode-equipped substrate having a substrate portion made of glass or synthetic resin and an electrode made of indium-tin alloy; depositing organic layers including a light emitting layer on the electrode-equipped substrate; and performing plasma treatment on the electrode-equipped substrate within an atmosphere of either a mixed gas of oxygen and any one of carbon tetrafluoride, hexafluoroethane, octafluoropropane and octafluorocyclobutane or a sole gas of carbon monoxide, carbon dioxide, nitrogen monoxide or nitrous oxide before depositing the organic layers on the electrode-equipped substrate.

According to this configuration, since the plasma treatment is carried out in an atmosphere of either a mixed gas of oxygen and any one of carbon tetrafluoride, hexafluoroethane, octafluoropropane and octafluorocyclobutane or a sole gas of carbon monoxide, carbon dioxide, nitrogen monoxide or nitrous oxide, unlike the conventional technique, the etching of the insulating film or cathode partition is difficult to occur. Since the substrate portion is made of synthetic resin that is flexible, a flexible organic EL element can be manufactured.

### BRIEF DESCRIPTION OF THE DRAWINGS

FIG. 1 is a sectional view of an organic EL element according to an embodiment of this invention;

FIG. 2 is a view showing a plasma generating device that is employed for manufacturing the organic EL element;

FIG. 3 is a graph showing the relationship between a preserving time at 100° C. and a driving voltage; and

FIG. 4 is a table showing a relationship between a preserving time at 100° C. and a driving voltage.

### DETAILED DESCRIPTION OF THE PREFFERED EMBODIMENTS

A first embodiment of this invention will be described with reference to accompanying drawings.

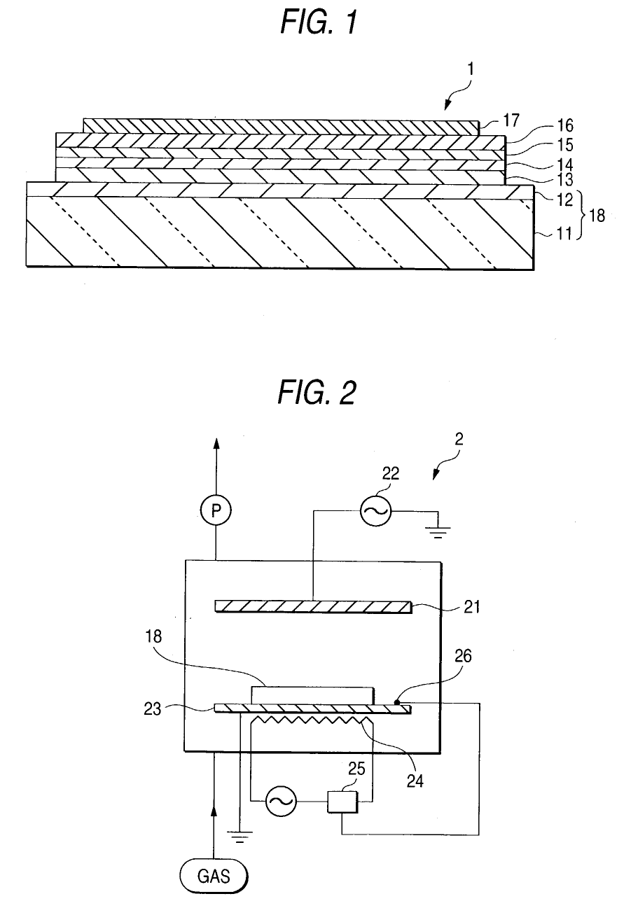

FIG. 1 shows an organic EL element 1 according to this embodiment. The organic EL element 1 includes a substrate portion 11, a transparent electrode (anode) 12 of an IZO film disposed on the substrate portion 11, a hole injecting layer 13 that is an organic layer deposited on the transparent electrode 12, a hole transporting layer 14 that is an organic layer deposited on the hole injecting layer 13, a light emitting layer 15 that is an organic layer deposited on the hole transporting layer 14, an electron injecting layer 16 deposited on the light emitting layer 15 and an electrode (cathode) 17 deposited on the electron injecting layer 16.

The substrate portion 11 is made of synthetic resin such as polycarbonate.

The hole transporting layer 14 is made of aromatic amine derivative such as N,N′-diphenyl-N,N′-(3-methylphenyl) -1,1′-bisphenyl-4,4′-diamine.

The light emitting layer 15 is made of π conjugate polymer such as tris-(8-quinolinolato) aluminium complex (Alq), bis (benzoquinolinolato) beryllium complex (BeBq), tri(dibenzoylmethyl)phenanthroline europium complex (Eu (DBM) 3 (Phen), ditoluic vynylbiphenyl (DTVBi), poly(p-phenylenevynylene) and polyalkylthiophene

The electrode 17 is made of aluminum, aluminum alloy, alloy of magnesium and silver, etc.

Such an organic EL element 1 is manufactured using a plasma generating apparatus 2 as shown in FIG. 2. The plasma generating apparatus 2 pre-treats an electrode-equipped substrate 18 (in which the transparent electrode 12 is provided on the substrate portion 11) by plasma treatment before the organic layers are deposited on the substrate 18.

The plasma generating apparatus 2 includes a discharge electrode 21 connected to a high frequency power source 22. A lower electrode 23 connected to ground is provided at a position opposite to the discharge electrode 21. When the plasma treatment is carried out, the electrode-equipped substrate 18 is placed on the lower electrode 23. In the vicinity below the lower electrode 23, a heater 24 is arranged for the electrode-equipped substrate 18. The heater 24 is provided with a controller 25 that detects and controls the heating temperature of the electrode-equipped substrate 18 with the aid of a temperature sensor 26 such as a thermo couple. The temperature sensor is arranged on the lower electrode 23.

The electrode-equipped substrate 18 is subjected to heat treatment at a temperature of about 200° C. or lower, e.g. 50° C. by the heater 24 as well as plasma treatment. The temperature of the heat treatment may be decided from the material of the substrate portion 11, that of the transparent electrode 12, etc.

The plasma treatment by the plasma generating apparatus 2 is carried out within atmosphere of (A) a mixed gas of oxygen and any one of nitrogen, argon, helium, neon and xenon, with an oxygen density of 5% or less; (B) a mixed gas of oxygen and any one of carbon tetrafluoride, hexafluoroethane, octafluoropropane and octafluorocyclobutane; or (C) a sole gas of nitrogen, argon, helium, neon, xenon, carbon monoxide, carbon dioxide, nitrogen monoxide or nitrous oxide.

An explanation will be given of a manufacturing method of an organic EL element 1.

First, IZO is sputtered on the substrate portion 11 to form an IZO film. A resist for an etching mask is applied to a predetermined portion of the IZO film and developed by photolithography. Thereafter, the IZO film is etched and thereafter the resist for an etching mask is removed. Thereby, the transparent electrode 12 patterned on the substrate portion 11 is provided so that the electrode-equipped substrate 18 is made.

The electrode-equipped substrate 18 is brush-cleaned. Thereafter, the electrode-equipped substrate 18 is transported to the plasma generating apparatus 2 and plasma-treated there. The electrode-equipped substrate 18 thus plasma-treated is put in an evaporator (not shown) . The hole injecting layer 13, hole transporting layer 14, light emitting layer 15, electron injecting layer 16 and electrode 17 are successively evaporated in this order.

Finally, a silicon nitride protection film is formed by plasma CVD to make thin film sealing.

According to this embodiment, the following advantages can be obtained.

Conventionally, the heat treatment at a temperature of 200° C. or lower caused a remarkable deterioration of the luminance when the organic EL element was preserved at a temperature of 100° C. On the other hand, according to this embodiment, since both the plasma treatment and heat treatment are carried out, even the heat treatment of 50° C. does not cause a deterioration of the luminance so that the electrode-equipped substrate 18 can be sufficiently treated. Thus, even when the substrate 11 is made of polycarbonate that has low heat-resistance of only 150° C. or lower, the organic EL element 1 can be manufactured without deteriorating its characteristics.

The substrate portion 11 may be made of synthetic resin. Since the synthetic resin is flexible, a flexible organic EL element 1 can be manufactured.

Since the heater 24 equipped with the controller 25 is used for heat-treating the electrode-equipped substrate 18, the heating temperature can be easily adjusted.

Unlike the conventional technique in which the plasma treatment with only oxygen or UV ozone treatment is performed, in this embodiment, the plasma treatment is made within atmosphere of (A) a mixed gas of oxygen and any one of nitrogen, argon, helium, neon and xenon, with an oxygen density of 5% or less; (B) a mixed gas of oxygen and any one of carbon tetrafluoride, hexafluoroethane, octafluoropropane and octafluorocyclobutane; or (C) a sole gas of nitrogen, argon, helium, neon, xenon, carbon monoxide, carbon dioxide, nitrogen monoxide or nitrous oxide. Therefore, the etching of the insulating film such as the resist or cathode partition is difficult to occur. Particularly, although the mixed gas (A) contains oxygen, the oxygen density is 5% or less. For this reason, the etching of the insulating film such as the resist or cathode partition can be prevented. Further, if the oxygen density of the mixed gas (B) is also 5% or less, using the mixed gas (B), the etching of the insulating film such as the resist or cathode partition can be effectively prevented.

Further, in this embodiment, the plasma treatment is carried out in a state where the electrode-equipped substrate 18 is placed on the lower electrode 23 located oppositely to the discharge electrode 21. This permits the damage to the electrode-equipped substrate 18 to be reduced as compared with the case where the electrode-equipped substrate 18 is placed on the side of the discharge electrode 21.

Next, an explanation will be given of the second embodiment of this invention. In the first embodiment, the transparent electrode 12 of the electrode-equipped substrate 18 is made of the IZO film. In the second embodiment, the transparent electrode 12 is made of an ITO film. The substrate portion is made of synthetic resin as in the first embodiment. The organic EL element according to this embodiment is manufactured in substantially the same way as in the first embodiment. However, the heat treatment is not carried out during the plasma treatment. The plasma treatment is carried out within an atmosphere of either a mixed gas of oxygen and any one of carbon tetrafluoride, hexafluoroethane, octafluoropropane and octafluorocyclobutane or a sole gas of carbon monoxide, carbon dioxide, nitrogen monoxide or nitrous oxide.

According to this embodiment, the following advantages can be obtained.

Since the plasma treatment is carried out within the atmosphere of the mixed gas or sole gas as described above, the etching of the insulating film such as the resist or cathode partition is difficult to occur unlike the conventional technique.

Since the substrate portion is made of synthetic resin that is flexible, a flexible organic EL element can be manufactured.

Incidentally, this invention should not be limited to the embodiments described above, but includes modifications or improvements within a range capable of attaining the object of this invention.

For example, the structure of the organic EL element 1 should not be limited to those in the embodiments described above. Specifically, the hole transporting layer 14 may not be provided. The electron transporting layer may be provided between the light emitting layer 15 and the electron injecting layer 16.

In the first embodiment, the substrate portion 11 is made of synthetic resin, but the substrate portion may be made of glass. In the first embodiment, the transparent electrode 12 is formed of an IZO film, but the transparent electrode may be made of ITO, gold, copper iodide, etc.

In the embodiments described above, the transparent electrode is patterned, but the transparent electrode may be an electrode equipped with an insulating film that conceals the edge of the pixel portion of the transparent electrode, or an electrode equipped with a cathode partition of an inverted tapered structure.

In the embodiments described above, the organic EL elements are sealed by the thin film of the silicon nitride protection film formed by the plasma CVD, but the organic EL element may be sealed by a can containing a desiccant.

In the embodiments described above, the organic layers such as the light emitting layer 15 are deposited by evaporation, but the organic layers may be deposited by ink jetting of high polymer.

In the embodiments described above, the substrate portion is made of polycarbonate, but the substrate portion may be made of polymethyl methacrylate, polyallylate, poly ether sulfone, polysulfone, polyethylene terephthalate, etc. Further, in the embodiments described above, the substrate portion is made of synthetic resin, but the substrate portion may be made of glass.

In order to confirm the effect of this invention, the following comparative experiments were performed.

### EXAMPLE

Using the plasma generating apparatus 2 employed in the embodiments described above, organic EL elements having the same structure as in the embodiments described above was manufactured. Two kinds of organic EL elements with the transparent electrodes of ITO and IZO were manufactured.

The plasma treatment was carried out within an atmosphere of a mixed gas of carbon tetrafluoride and oxygen (oxygen density of 5%) under the conditions of a temperature of the electrode-equipped substrate of 50° C., a high frequency of 13.56 MHz and pressure of 0.9 Torr (120Pa). The flow rate of the mixed gas was 200SCCM (the gas flow rate calibrated at 0° C. and 1 atom is 200 cc/min), the RF power was 50 mW/cm², and the treatment time was 10 minutes.

After the organic EL elements thus manufactured were placed in an oven maintained at 100° C., changes in the driving voltage with respect to 100° C. preserving time were observed with the current density fixed to 7.5 mA/cm².

### [COMPARATIVE EXAMPLE]

Two kinds of organic EL elements were manufactured in the same manner as in the example described above, but were not plasma-treated.

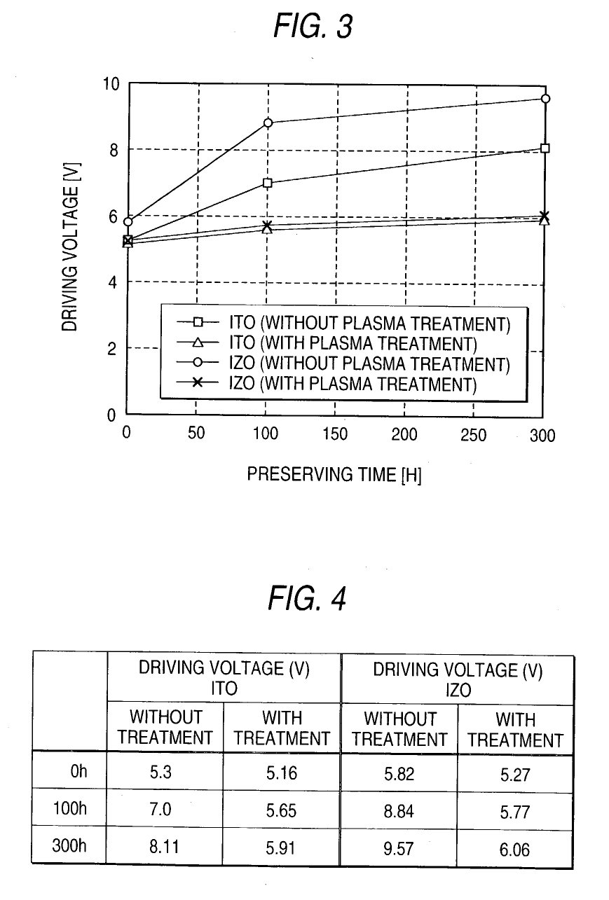

The results of the example and comparative example are shown in a graph of FIG. 3 and a table of FIG. 4.

As seen from the graph of FIG. 3 and the table of FIG. 4, the organic EL elements subjected to the plasma treatment provides a small voltage increase irrespective of the kind of the transparent electrode even in case of being preserved at 100° C. for long period of time. On the other hand, the organic EL elements not subjected to the plasma treatment provides a voltage increase with elapse of the 100° C. preserving time.

Comparison was made in light emission between the organic EL elements preserved for 500 hours at 100° C. As a result of comparison, the organic EL element subjected to the plasma treatment brightly emitted light at 5V. On the other hand, the organic EL element not subjected to the plasma treatment dimly emitted light at even 9 V, and some areas not emitting light were observed.

The experimental result described above conspicuously indicated the effect of this invention that the electrode-equipped substrate having the substrate portion of synthetic resin can be treated without deteriorating the characteristics of the organic EL element.

According to this invention, there is provided a manufacturing method of an organic EL element which can pre-treat an electrode-equipped substrate without deteriorating the characteristics of the organic EL element.

What is claimed is:

1. A manufacturing method of an organic electroluminescent element, comprising:
preparing a electrode-equipped substrate having a substrate portion made of glass or synthetic resin;
depositing organic layers including a light emitting layer on the electrode-equipped substrate; and
performing both plasma treatment and heat treatment on the electrode-equipped substrate before depositing the organic layers on the electrode-equipped substrate.

2. A manufacturing method of an organic electroluminescent element according to claim 1, wherein the plasma treatment is carried out within an atmosphere of (A) a mixed gas of oxygen and any one of nitrogen, argon, helium, neon and xenon, with an oxygen density of 5% or less; (B) a mixed gas of oxygen and any one of carbon tetrafluoride, hexafluoroethane, octafluoropropane and octafluorocyclobutane; or (C) a sole gas of nitrogen, argon, helium, neon, xenon, carbon monoxide, carbon dioxide, nitrogen monoxide or nitrous oxide.

3. A manufacturing method of an organic electroluminescent element according to claim 1, wherein the heat treatment is carried out using a heater that is disposed in the vicinity of the electrode-equipped substrate.

4. A manufacturing method of an organic electroluminescent element according to claim 2, wherein the heat treatment is carried out using a heater that is disposed in the vicinity of the electrode-equipped substrate.

5. A manufacturing method of an organic electroluminescent element, comprising:
preparing a electrode-equipped substrate having a substrate portion made of glass or synthetic resin and an electrode made of indium-tin alloy;
depositing organic layers including a light emitting layer on the electrode-equipped substrate; and
performing plasma treatment on the electrode-equipped substrate within an atmosphere of either a mixed gas of oxygen and any one of carbon tetrafluoride, hexafluoroethane, octafluoropropane and octafluorocyclobutane or a sole gas of carbon monoxide, carbon dioxide, nitrogen monoxide or nitrous oxide before depositing the organic layers on the electrode-equipped substrate.
